(19) United States
(12) Patent Application Publication
(10) Pub. No.: US 2026/0026214 A1
(43) Pub. Date: Jan. 22, 2026

(54) Thin Film Transistor Having Hydrogen Blocking Layer and Display Apparatus Comprising the Same

(71) Applicant: LG Display Co., Ltd., Seoul (KR)

(72) Inventors: Dohyung Lee, Paju-si (KR); JuHeyuck Baeck, Paju-si (KR); GaWon Yang, Paju-si (KR)

(21) Appl. No.: 19/246,703

(22) Filed: Jun. 24, 2025

(30) Foreign Application Priority Data
Jul. 22, 2024 (KR) 10-2024-0096459

(51) Int. Cl. H10K 59/126; H10K 59/124

(52) U.S. Cl. CPC H10K 59/126; H10K 59/124

(57) ABSTRACT

A thin film transistor having a hydrogen blocking layer and a display apparatus including the same are disclosed. The thin film transistor includes an active layer, a gate electrode on the active layer, an insulating layer on the gate electrode, a hydrogen blocking layer on the insulating layer, a first barrier connected to the hydrogen blocking layer, and a second barrier spaced apart from the first barrier and connected to the hydrogen blocking layer. The first barrier extends from the hydrogen blocking layer, penetrates the insulating layer, and contacts one of a source connection part and a drain connection part of the active layer.

### CROSS-REFERENCE TO RELATED APPLICATION

This application claims the priority benefit of priority of the Republic of Korea Patent Application No. 10-2024-0096459 filed on Jul. 22, 2024, which is hereby incorporated by reference in its entirety.

### TECHNICAL FIELD

The present disclosure generally relates to display technologies, and particularly to, for example, without limitation, a thin film transistor having a hydrogen blocking layer and a display apparatus including the same.

### DESCRIPTION OF THE RELATED ART

Transistors are widely used as switching devices or driving devices in the field of electronic devices. In particular, thin film transistors are widely used as switching devices in display apparatuses such as liquid crystal display apparatuses or organic light emitting devices because they may be manufactured on glass base substrates or plastic base substrates.

Thin film transistors can be classified into amorphous silicon thin film transistors in which amorphous silicon is used as the active layer, polycrystalline silicon thin film transistors in which polycrystalline silicon is used as the active layer, and oxide semiconductor thin film transistors in which oxide semiconductor is used as the active layer, based on the material constituting the active layer.

Among these, oxide semiconductor thin film transistors or oxide semiconductor TFTs with high mobility and large resistance changes depending on the oxygen content have the advantage of being able to easily obtain desired properties. In addition, since the oxide constituting the active layer may be formed at a relatively low temperature during the manufacturing process of oxide semiconductor thin film transistors, the manufacturing cost is low. Since oxide semiconductors are transparent due to the nature of oxides, they are also advantageous in implementing transparent displays.

### SUMMARY

However, oxide semiconductors are sensitive to hydrogen. For example, the electrical characteristics of oxide semiconductors can change when in contact with hydrogen. Hydrogen may cause changes in the characteristics of oxide semiconductors or cause the physical properties of oxide semiconductors to become unstable. In particular, hydrogen that has penetrated into oxide semiconductors from other layers or from the outside makes the physical properties of oxide semiconductors unstable and makes it difficult to predict changes in the electrical characteristics of oxide semiconductor thin film transistors.

Therefore, in the process of manufacturing oxide semiconductor thin film transistors, the content of hydrogen is strictly controlled, and it is necessary to prevent or at least reduce hydrogen from penetrating into the oxide semiconductor thin film transistor after manufacturing the oxide semiconductor thin film transistor.

Recently, hydrogen blocking layers, or the like are being used to prevent or at least reduce changes in the electrical characteristics of oxide semiconductor thin film transistors due to hydrogen.

One embodiment of the present disclosure is to provide a thin film transistor having excellent hydrogen blocking characteristics.

One embodiment of the present disclosure is to provide a thin film transistor including a hydrogen blocking layer and a barrier connected to the hydrogen blocking layer.

Another embodiment of the present disclosure is to provide a display apparatus having excellent hydrogen blocking characteristics, including a thin film transistor as described above.

Another embodiment of the present disclosure is to provide a display apparatus including a pixel electrode connected to a hydrogen blocking layer.

In order to achieve the above described technical subject, one embodiment of the present disclosure provides a thin film transistor comprising an active layer, a gate electrode on the active layer, an insulating layer on the gate electrode, a hydrogen blocking layer on the insulating layer, a first barrier connected to the hydrogen blocking layer, and a second barrier spaced from the first barrier and connected to the hydrogen blocking layer, wherein the active layer includes a channel portion overlapping the gate electrode, a source connection part connected to one side of the channel portion, and a drain connection part connected to the other side of the channel portion, wherein the first barrier extends from the hydrogen blocking layer and contacts one of the source connection part and the drain connection part by penetrating the insulating layer, and the second barrier extends from the hydrogen blocking layer and is spaced apart from the first barrier with the gate electrode being therebetween.

The second barrier may overlap the other one of the source connection part and the drain connection part in a plan view, and may be spaced apart from the other one of the source connection part and the drain connection part.

The first barrier may be disposed in a first hole formed in the insulating layer along the thickness direction, and the second barrier may be disposed in a second hole formed in the insulating layer along the thickness direction.

Each of the first hole and the second hole may have a slit shape.

The thin film transistor may further include a third barrier extending from the hydrogen blocking layer, and the third barrier extend may not overlap the gate electrode, the source connection part, or the drain connection part.

The third barrier may contact the first barrier and the second barrier.

The first barrier, the second barrier, and third barrier may form an area defined by a U-shaped boundary in a plan view, and the channel portion may be disposed in the area defined by the U-shaped boundary in a plan view.

The thin film transistor may further include a light blocking layer, and the light blocking layer may be spaced apart from the active layer, wherein the active layer may be disposed between the gate electrode and the light blocking layer, wherein the light blocking layer may overlap the channel portion of the active layer, and wherein the third barrier may contact with the light blocking layer.

The thin film transistor may further include a buffer layer, and the buffer layer may be disposed between the light blocking layer and the active layer, and the third barrier may penetrate at least the insulating layer and the buffer layer to contact the light blocking layer.

The hydrogen blocking layer, the first barrier, the second barrier, and the third barrier are formed of the same material in the same process.

The hydrogen blocking layer, the first barrier, and the second barrier include at least one selected from tungsten W, titanium Ti, a molybdenum-titanium alloy MoTi, chromium Cr, vanadium V, and manganese Mn.

The hydrogen blocking layer, the first barrier, and the second barrier include at least one selected from tungsten oxide WOx and chromium oxide CrOx.

Another embodiment of the present disclosure provides a display apparatus comprises a display element, and a pixel driver driving the display element, wherein the pixel driver includes a thin film transistor, wherein the thin film transistor comprises an active layer, a gate electrode on the active layer, an insulating layer on the gate electrode, a hydrogen blocking layer on the insulating layer, a first barrier connected to the hydrogen blocking layer, and a second barrier spaced apart from the first barrier and connected to the hydrogen blocking layer, wherein the active layer comprising, a channel portion overlapping the gate electrode, a source connection part connected to one side of the channel portion, and a drain connection part connected to the other side of the channel portion, wherein the first barrier extends from the hydrogen blocking layer and contacts one of the source connection part and the drain connection part by penetrating the insulating layer, and wherein the second barrier extends from the hydrogen blocking layer and is spaced apart from the first barrier with the gate electrode being therebetween.

The display apparatus may further include a third barrier, and the third barrier may extend from the hydrogen blocking layer, wherein the third barrier may not overlap the gate electrode, the source connection part, or the drain connection part.

The third barrier may contact the first barrier and the second barrier.

The display apparatus may further include a light blocking layer, and the light blocking layer may be spaced apart from the active layer, wherein the active layer may be disposed between the gate electrode and the light blocking layer, wherein the light blocking layer may overlap the channel portion of the active layer, and wherein the third barrier may contact the light blocking layer.

The display element may include a first electrode, and the first electrode may be connected to the hydrogen blocking layer.

At least a portion of the first electrode may be disposed on the hydrogen blocking layer and may contact the hydrogen blocking layer.

The first electrode may include a first region overlapping the hydrogen blocking layer, and a second region not overlapping the hydrogen blocking layer, wherein the second region may be light transmissive.

The first electrode may be disposed on the hydrogen blocking layer entirely, and the first electrode may have a light reflecting property.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a plan view of a thin film transistor according to one embodiment of the present disclosure.

FIG. 2 is a cross-sectional view taken along line I-I′ of FIG. 1 according to one embodiment of the present disclosure.

FIG. 3 is a cross-sectional view taken along line II-II′ of FIG. 1 according to one embodiment of the present disclosure.

FIG. 4 is a cross-sectional view of a thin film transistor according to another embodiment of the present disclosure.

FIG. 5 is a cross-sectional view of a thin film transistor according to another embodiment of the present disclosure.

FIG. 6 is a cross-sectional view of a thin film transistor according to another embodiment of the present disclosure.

FIG. 7 is a partial plan view of a display apparatus according to another embodiment of the present disclosure.

FIG. 8 is a cross-sectional view taken along line III-III′ of FIG. 7 according to one embodiment of the present disclosure.

FIG. 9 is a cross-sectional view taken along line IV-IV′ of FIG. 7 according to one embodiment of the present disclosure.

FIG. 10 is a partial plan view of a display apparatus according to another embodiment of the present disclosure.

FIG. 11 is a cross-sectional according to one embodiment of the present disclosure view taken along line V-V′ of FIG. 10 according to one embodiment of the present disclosure.

FIGS. 12A and 12B illustrate graphs of the hydrogen content included in a thin film transistor according to one embodiment of the present disclosure.

FIG. 13 is a positive-bias temperature stress (PBTS) graph for a thin film transistor according to one embodiment of the present disclosure.

FIG. 14 is a schematic diagram of a display apparatus according to another embodiment of the present disclosure.

FIG. 15 is a circuit diagram for one pixel of FIG. 14 according to one embodiment of the present disclosure.

FIG. 16 is a plan view of the pixels of FIG. 15 according to one embodiment of the present disclosure.

FIG. 17 is a cross-sectional view taken along line VI-VI′ of FIG. 16 according to one embodiment of the present disclosure.

FIG. 18 is a cross-sectional view taken along line VII-VII′ of FIG. 16 according to one embodiment of the present disclosure.

FIG. 19 is a cross-sectional view of a display apparatus according to another embodiment of the present disclosure.

FIG. 20 is a circuit diagram for one pixel of a display apparatus according to another embodiment of the present disclosure.

FIG. 21 is a plan view of the pixels of FIG. 20 according to one embodiment of the present disclosure.

FIG. 22 is a circuit diagram for one pixel of a display apparatus according to another embodiment of the present disclosure.

FIG. 23 is a schematic diagram of a portion of a display panel of a display apparatus according to another embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily obscure a gist of the inventive concept, the detailed description thereof will be omitted or may be briefly provided. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

The advantages and features of the present disclosure, and the method for achieving them, will become clear with reference to the embodiments described in detail below together with the accompanying drawings. However, the present disclosure is not limited to the embodiments disclosed below, but may be implemented in various different forms. These embodiments are only intended to make the disclosure of the present disclosure complete and to enable those skilled in the art to easily understand the disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

The shapes, sizes, ratios, angles, numbers, or the like disclosed in the drawings for explaining embodiments of the present disclosure are exemplary, and the present disclosure is not limited to the matters illustrated in the drawings. The same components may be referred to by the same reference numerals throughout the specification. In addition, in explaining the present disclosure, if it is determined that a detailed description of a related known technology may unnecessarily obscure the gist of the present disclosure, the detailed description is omitted.

In this specification, when the words “includes,” “has,” and “comprising,” are used, other parts may be added unless the expression “only” is used. When a component is expressed in the singular, the plural is included unless otherwise explicitly stated.

When interpreting a component, it is interpreted as including the error range even if there is no separate explicit description.

When describing a positional relationship, for example, when the positional relationship between two parts is described as ‘on’, ‘above’, ‘below’, ‘next to’, or the like, one or more other parts can be located between the two parts, unless the expression ‘right’ or ‘directly’ is used.

The spatially relative terms “below,” “beneath,” “lower,” “above,” “upper,” and the like can be used to easily describe the relationship of one element or component to another element or component, as illustrated in the drawings. The spatially relative terms should be understood to include different orientations of the elements during use or operation in addition to the orientations depicted in the drawings. For example, if an element illustrated in the drawings is flipped over, an element described as “below” or “beneath” another element may end up being placed “above” the other element. Thus, the exemplary term “below” can include both the above and below directions. Likewise, the exemplary term “above” or “above” can include both the above and below directions.

When describing a temporal relationship, for example, when describing a temporal relationship such as ‘after’, ‘following’, ‘next to’, or ‘before’, it can also include cases where there is no continuity, as long as the expression ‘right away’ or ‘directly’ is not used.

Although the terms first, second, or the like are used to describe various components, these components are not limited by these terms. These terms are only used to distinguish one component from another. Accordingly, a first component referred to below may also be a second component within the technical concept of the present disclosure.

The term “at least one of” should be understood to include all combinations that can be presented from one or more of the associated items. For example, the meaning of “at least one of the first, second, and third items” can mean not only each of the first, second, or third items, but also all combinations of items that can be presented from two or more of the first, second, and third items.

The individual features of the various embodiments of the present disclosure may be partially or wholly combined or combined with each other, and may be technically linked and driven in various ways, and each embodiment may be implemented independently of each other or may be implemented together in a related relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

It will be apparent to those skilled in the art that various modifications and variations can be made to the embodiments of the present disclosure without departing from the technical idea or scope of the present disclosure. Thus, it is intended that the present disclosure covers the modifications and variations of this disclosure provided they come within the scope of the appended claims and their equivalents.

Hereinafter, a thin film transistor and a display apparatus including the same according to an embodiment of the present disclosure will be described in detail with reference to the attached drawings. When adding reference symbols to components in each drawing, the same components may have the same symbols as much as possible even if they are shown in different drawings.

In embodiments of the present disclosure, the source electrode and the drain electrode are distinct, but the source electrode and the drain electrode may be interchanged. For example, the source electrode according to one embodiment may become the drain electrode in another embodiment, and the drain electrode according to one embodiment may become the source electrode in another embodiment.

In the embodiments of the present disclosure, for the convenience of explanation, the source region and the source electrode are distinguished, and the drain region and the drain electrode are distinguished, but the embodiments of the present disclosure are not limited thereto. The source region may be the source electrode, and the drain region may be the drain electrode. In addition, the source region may be the drain electrode, and the drain region may be the source electrode.

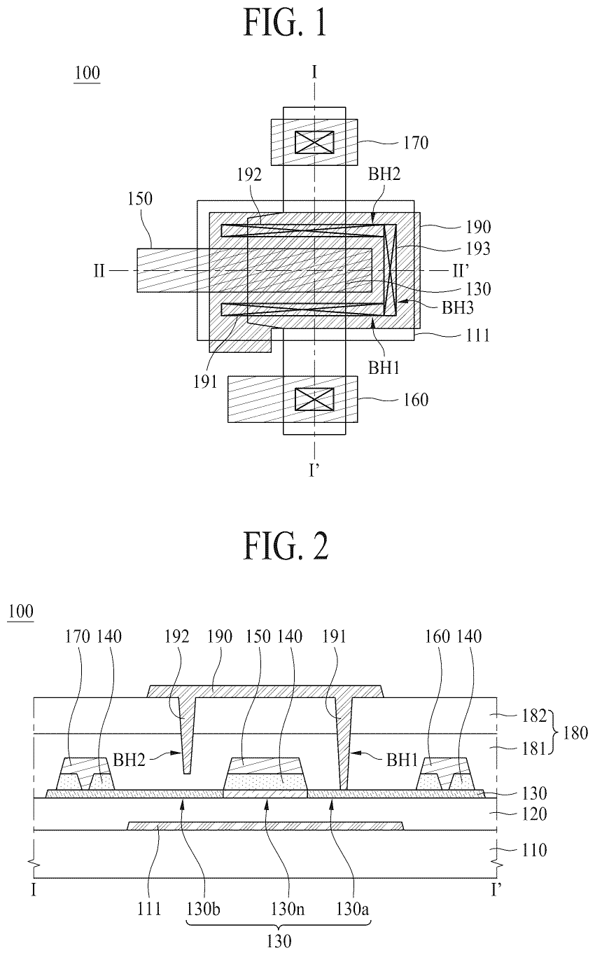

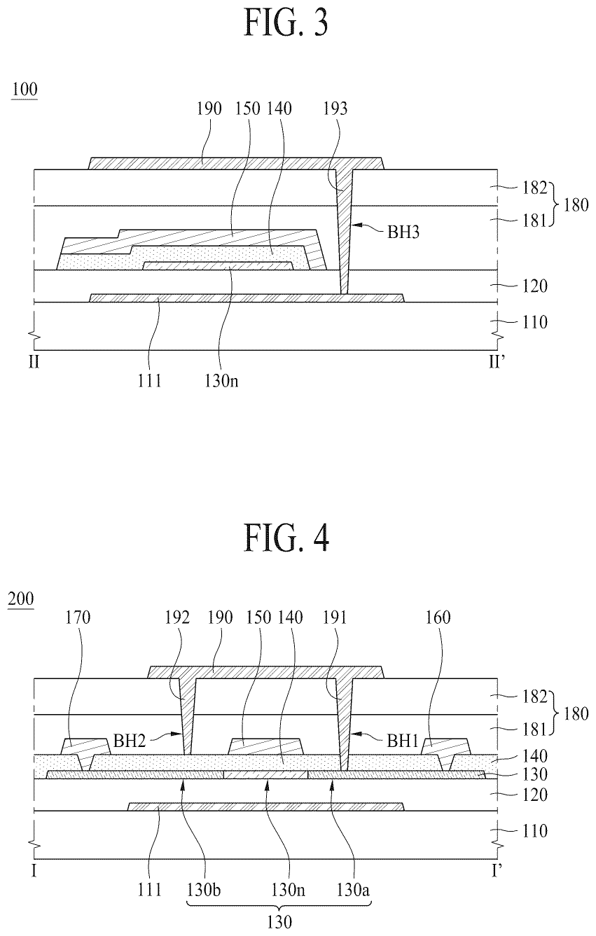

FIG. 1 is a plan view of a thin film transistor 100 according to one embodiment of the present disclosure, FIG. 2 is a cross-sectional view taken along line I-I′ of FIG. 1 according to one embodiment of the present disclosure, and FIG. 3 is a cross-sectional view taken along line II-II′ of FIG. 1 according to one embodiment of the present disclosure.

Referring to FIGS. 1, 2, and 3, a thin film transistor 100 according to one embodiment of the present disclosure includes an active layer 130, a gate electrode 150 on the active layer 130, an insulating layer 180 on the gate electrode 150, a hydrogen blocking layer 190 on the insulating layer 180, a first barrier 191 connected to the hydrogen blocking layer 190, and a second barrier 192 spaced apart from the first barrier 191 and connected to the hydrogen blocking layer 190. In addition, the thin film transistor 100 may include a source electrode 160 and a drain electrode 170 spaced apart from each other and electrically connected to the active layer 130, respectively.

The active layer 130 includes a channel portion 130n overlapping with the gate electrode 150, a source connection part 130a connected to one side of the channel portion 130n, and a drain connection part 130b connected to the other side of the channel portion 130n.

The first barrier 191 extends from the hydrogen blocking layer 190 and may penetrate the insulating layer 180 to contact either the source connection part 130a or the drain connection part 130b. The second barrier 192 extends from the hydrogen blocking layer 190 and may be spaced apart from the first barrier 191 with the gate electrode 150 therebetween.

Referring to FIGS. 2 and 3, a thin film transistor 100 may be disposed on a substrate 110.

The substrate 110 supports the components of the thin film transistor 100. Anything that supports the thin film transistor 100 may be called the substrate 110 without limitation.

Glass or plastic may be used as the substrate 110. A transparent plastic having flexible properties, such as polyimide, may be used as the plastic. When polyimide is used as the substrate 110, a heat resistant polyimide capable of withstanding high temperatures may be employed in consideration of high-temperature deposition processes performed on the substrate 110.

A light blocking layer 111 may be disposed on the substrate 110. The light blocking layer 111 blocks light incident from the outside, thereby protecting the channel portion 130n of the active layer 130.

The light blocking layer 111 may be made of a material having light blocking properties. The light blocking layer 111 may include at least one of an aluminum based metal such as aluminum (Al) or an aluminum alloy, a molybdenum based metal such as molybdenum (Mo) or a molybdenum alloy, chromium (Cr), tantalum (Ta), neodymium (Nd), titanium (Ti), and iron (Fe).

According to one embodiment of the present disclosure, the light blocking layer 111 may have electrical conductivity. The light blocking layer 111 may be electrically connected to either the source electrode 160 or the drain electrode 170.

Referring to FIG. 3, the light blocking layer 111 may be connected to the hydrogen blocking layer 190 through the third barrier 193. Referring to FIG. 2, the hydrogen blocking layer 190 is connected to the source connection part 130a through the first barrier 191. Accordingly, the light blocking layer 111 may be connected to the source connection part 130a through the third barrier 193, the hydrogen blocking layer 190, and the first barrier 191.

The shading layer may be omitted.

Referring to FIGS. 2 and 3, a buffer layer 120 is disposed on a light blocking layer 111. The buffer layer 120 may be made of an insulating material. For example, the buffer layer 120 may include at least one of an insulating material such as silicon oxide, silicon nitride, and a metal oxide. The buffer layer 120 may have a single film structure or a multi-film structure.

The buffer layer 120 may protect the channel portion 130n by blocking air and moisture. In addition, the surface of the upper portion of the substrate 110 may be made uniform by the buffer layer 120.

The active layer 130 is disposed on the substrate 110. Referring to FIGS. 2 and 3, the active layer 130 may be disposed on the buffer layer 120 located on the substrate 110.

According to one embodiment of the present disclosure, the active layer 130 may include an oxide semiconductor material. Specifically, the channel portion 130n, the source connection part 130a, and the drain connection part 130b included in the active layer 130 may include an oxide semiconductor material.

The oxide semiconductor material may include at least one of, for example, IGZO (InGaZnO) based, IGZTO (InGaZnSnO) based, IZO (InZnO) based, IGO (InGaO) based, ITO (InSnO) based, ITZO (InSnZnO) based, InO (InO) based, ZnO based, and FIZO (FeInZnO) based oxide semiconductor materials. However, one embodiment of the present disclosure is not limited thereto, and the active layer 130 may be formed by other oxide semiconductor materials known in the art.

The channel portion 130n overlaps with the gate electrode 150. The channel portion 130n has semiconductor characteristics. Depending on the voltage applied to the gate electrode 150, the channel portion 130n may have electrical characteristics like a conductor or characteristics like an insulator.

According to one embodiment of the present disclosure, the source connection part 130a and the drain connection part 130b do not overlap with the gate electrode 150. The source connection part 130a and the drain connection part 130b may be referred to as a conductorized region.

A source connection part 130a and a drain connection part 130b may be formed by selective conductorization of the active layer 130. In detail, a source connection part 130a and a drain connection part 130b may be formed by selective conductorization of an oxide semiconductor material constituting the active layer 130.

According to one embodiment of the present disclosure, selective conductorization refers to improving the conductivity of a selected portion of the active layer 130 or imparting conductivity to the selected portion. The selectively conductorized portion of the active layer 130 has excellent electrical conductivity and can function as a wiring portion.

According to one embodiment of the present disclosure, selective conductorization may be achieved, for example, by doping a selected region of the active layer 130 with a dopant. In this case, the source connection part 130a and the drain connection part 130b may include a dopant.

According to one embodiment of the present disclosure, doping may be accomplished by ion implantation. Dopant ions may be doped into a selected region of the active layer 130 by ion implantation.

According to one embodiment of the present disclosure, the dopant may include at least one of boron (B), phosphorus (P), fluorine (F), and hydrogen (H).

According to one embodiment of the present disclosure, an active layer 130 is formed by an oxide semiconductor material, and a source connection part 130a and a drain connection part 130b may be formed by doping a dopant into selected portions of the active layer 130. The source connection part 130a and the drain connection part 130b may be referred to as regions doped by ion implantation.

However, one embodiment of the present disclosure is not limited thereto, and the source connection part 130a and the drain connection part 130b may be conductorized by other methods. According to one embodiment of the present disclosure, conductorization may be imparted to the source connection part 130a and the drain connection part 130b by plasma treatment. For example, during the patterning process of the gate insulating layer 140 or the gate electrode 150, selective conductorization may be achieved by plasma treatment, thereby forming the source connection part 130a and the drain connection part 130b.

According to one embodiment of the present disclosure, a region of the active layer 130 that is not doped with a dopant and is not conductorized may become a channel portion 130n.

According to one embodiment of the present disclosure, the source connection part 130a and the drain connection part 130b each have electrical characteristics similar to those of a conductor. For example, the source connection part 130a and the drain connection part 130b may each have a resistivity of 10⁻⁴ Ωcm or less.

Referring to FIGS. 2 and 3, a gate insulating layer 140 is disposed on an active layer 130. The gate insulating layer 140 may include at least one of silicon oxide, silicon nitride, and metal oxide. The gate insulating layer 140 may have a single layer structure or a multilayer structure. The gate insulating layer 140 protects the channel portion 130n.

The gate electrode 150 is disposed on the gate insulating layer 140. The gate electrode 150 is formed to overlap with the channel portion 130n of the active layer 130.

Referring to FIG. 2, the gate insulating layer 140 may have a patterned shape. For example, the gate insulating layer 140 may be patterned into a shape corresponding to the gate electrode 150.

The gate insulating layer 140 and the gate electrode 150 may be patterned in one process. During the patterning process of the gate insulating layer 140 and the gate electrode 150, selective conductorization may be performed, so that the source connection part 130a and the drain connection part 130b may be formed. Specifically, during the patterning process of the gate insulating layer 140 and the gate electrode 150, selective conductorization may be performed in a plasma treatment process, so that the source connection part 130a and the drain connection part 130b may be formed.

The gate electrode 150 may include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The gate electrode 150 may also have a multilayer structure including at least two conductive layers having different physical properties.

In addition, referring to FIG. 2, a source electrode 160 and a drain electrode 170 may be disposed on a gate insulating layer 140. The gate insulating layer 140 may be patterned into shapes corresponding to each of the source electrode 160 and the drain electrode 170. As illustrated in FIG. 2, when the source electrode 160 and the drain electrode 170 are disposed on the gate insulating layer 140, the gate insulating layer 140 may be patterned into shapes corresponding to each of the source electrode 160 and the drain electrode 170.

In one embodiment of the present disclosure illustrated in FIG. 2, the source electrode 160 and the drain electrode 170 may be made of the same material as the gate electrode 150. The gate electrode 150, the source electrode 160, and the drain electrode 170 may be made of the same material through the same process.

According to one embodiment of the present disclosure, the source electrode 160 may be connected to the source connection part 130a. Specifically, the source electrode 160 is electrically connected to the source connection part 130a through a contact hole and may transmit an electrical signal to the channel portion 130n.

The drain electrode 170 is spaced apart from the source electrode 160 and may be connected to the drain connection part 130b. Specifically, the drain electrode 170 is electrically connected to the drain connection part 130b through a contact hole and may transmit an electrical signal to the channel portion 130n.

The source electrode 160 and the drain electrode 170 may be omitted. When the source electrode 160 and the drain electrode 170 are omitted, the source connection part 130a may become the source electrode, and the drain connection part 130b may become the drain electrode.

The source electrode 160 and drain electrode 170 may be interchanged.

Referring to FIGS. 2 and 3, an insulating layer 180 is disposed on the gate insulating layer 140 and the gate electrode 150. The insulating layer 180 may be made of an insulating material. The insulating layer 180 may be made of an organic material, an inorganic material, or a laminate of an organic layer and an inorganic layer.

According to one embodiment of the present disclosure, as shown in FIGS. 2 and 3, the insulating layer 180 may include a first insulating layer 181 and a second insulating layer 182.

Specifically, the first insulating layer 181 may be disposed on the gate electrode 150. The first insulating layer 181 may also be referred to as an interlayer insulating layer. The first insulating layer 181 may be made of an insulating material. The first insulating layer 181 may be made of an organic material, an inorganic material, or a laminate of an organic layer and an inorganic layer.

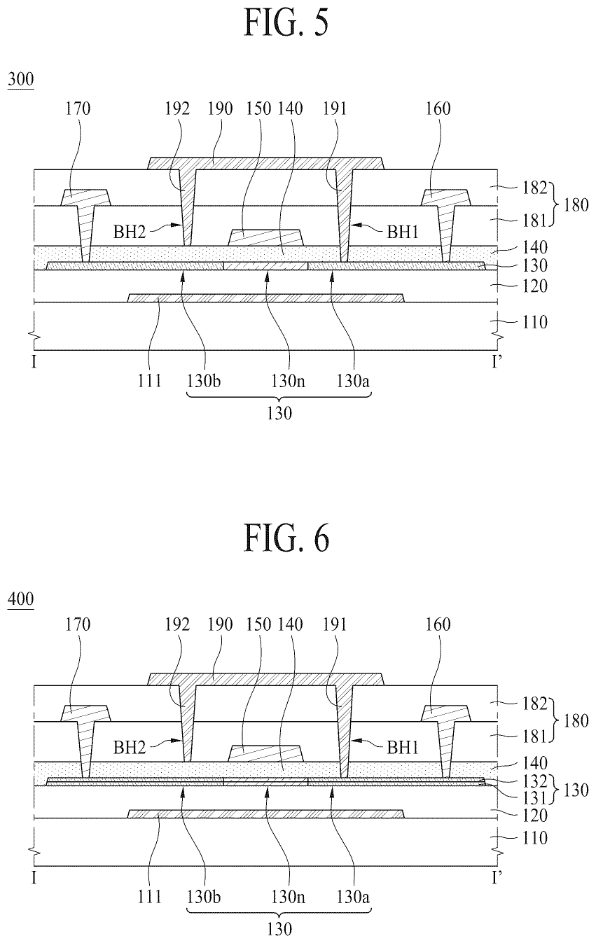

Unlike the embodiment disclosed in FIG. 2, the source electrode 160 and the drain electrode 170 may be disposed on the first insulating layer 181 see FIG. 5.

A second insulating layer 182 may be disposed on the first insulating layer 181. The second insulating layer 182 flattens the upper portion of the thin film transistor 100 and protects the thin film transistor 100. The second insulating layer 182 may also be referred to as a flattening layer.

A hydrogen blocking layer 190 is disposed on the insulating layer 180. Referring to FIGS. 2 and 3, the hydrogen blocking layer 190 may be disposed on the second insulating layer 182.

The hydrogen blocking layer 190 has a function of blocking hydrogen. Specifically, the hydrogen blocking layer 190 may block hydrogen flowing into the channel portion 130n of the active layer 130. Specifically, the hydrogen blocking layer 190 may block hydrogen flowing into the channel portion 130n from a layer disposed on top of the insulating layer 180.

The hydrogen blocking layer 190 may include, for example, at least one of tungsten (W), titanium (Ti), an alloy of molybdenum and titanium (MoTi), chromium (Cr), vanadium (V), and manganese (Mn). In detail, the hydrogen blocking layer 190 may include at least one of tungsten oxide (WOx) and chromium oxide (CrOx).

The hydrogen blocking layer 190 has excellent hydrogen bonding capability. The hydrogen blocking layer 190 may easily bond with hydrogen (H) and forms a stable bond with hydrogen (H). The hydrogen blocking layer 190 and hydrogen (H) form a stable bond, and the hydrogen (H) bonded to the hydrogen blocking layer 190 may not be easily separated.

The hydrogen blocking layer 190 may have a porous membrane structure. The hydrogen blocking layer 190 having a porous membrane structure may effectively capture hydrogen and block hydrogen movement.

Referring to FIGS. 2 and 3, a first barrier 191, a second barrier 192, and a third barrier 193 may be disposed within the insulating layer 180.

According to one embodiment of the present disclosure, the first barrier 191, the second barrier 192, and the third barrier 193 may be made of the same material as the hydrogen blocking layer 190. The first barrier 191, the second barrier 192, and the third barrier 193 may be formed by the same process using the same material as the hydrogen blocking layer 190. The first barrier 191, the second barrier 192, and the third barrier 193 may be formed integrally with the hydrogen blocking layer 190.

According to one embodiment of the present disclosure, the hydrogen blocking layer 190, the first barrier 191, the second barrier 192, and the third barrier 193 may have electrical conductivity. Therefore, the hydrogen blocking layer 190, the first barrier 191, the second barrier 192, and the third barrier 193 may function as wiring and electrodes.

According to one embodiment of the present disclosure, the first barrier 191 and the second barrier 192 may include at least one of tungsten (W), titanium (Ti), an alloy of molybdenum and titanium (MoTi), chromium (Cr), vanadium (V), and manganese (Mn). The first barrier 191 and the second barrier 192 may include at least one of tungsten oxide (WOx) and chromium oxide (CrOx).

The first barrier 191 extends from the hydrogen blocking layer 190 and may penetrate the insulating layer 180. The first barrier 191 may penetrate the insulating layer 180 and contact either the source connection part 130a or the drain connection part 130b.

In FIG. 2, a structure is disclosed in which a first barrier 191 penetrates the insulating layer 180 and contacts with a source connection part 130a. However, one embodiment of the present disclosure is not limited thereto, and the first barrier 191 may penetrate the insulating layer 180 and make contact with a drain connection part 130b.

The second barrier 192 may be spaced apart from the first barrier 191 and connected to the hydrogen blocking layer 190. The second barrier 192 may extend from the hydrogen blocking layer 190 and may be disposed spaced apart from the first barrier 191 with the gate electrode 150 interposed therebetween.

Referring to FIGS. 1 and 2, the second barrier 192 may be spaced apart from and overlap the other one of the source connection part 130a and the drain connection part 130b.

In FIG. 2, a structure is disclosed in which the second barrier 192 overlaps the drain connection part 130b and is spaced apart from the drain connection part 130b. However, one embodiment of the present disclosure is not limited thereto, and the second barrier 192 may overlap the source connection part 130a and be spaced apart from the source connection part 130a.

According to one embodiment of the present disclosure, the hydrogen blocking layer 190, the first barrier 191, and the second barrier 192 may have electrical conductivity and are electrically connected to each other.

Referring to FIG. 2, the first barrier 191 contacts with the source connection part 130a, and the hydrogen blocking layer 190, the first barrier 191, and the second barrier 192 are connected to each other. Therefore, the same voltage as the source connection part 130a may be applied to the hydrogen blocking layer 190, the first barrier 191, and the second barrier 192.

The first barrier 191 may be disposed in the first hole BH1 formed in the insulating layer 180 along the thickness direction. The second barrier 192 may be disposed in the second hole BH2 formed in the insulating layer 180 along the thickness direction. Here, the thickness direction refers to the direction perpendicular to the surface of the substrate 110 in the up-down direction of the drawing.

According to one embodiment of the present disclosure, the first hole BH1 and the second hole BH2 may each have a slit shape. Accordingly, the first barrier 191 disposed in the first hole BH1 may have a plate shape or a barrier shape. In addition, the second barrier 192 disposed in the second hole BH2 may also have a plate shape or a barrier shape.

Referring to FIGS. 1 and 3, a thin film transistor 100 according to one embodiment of the present disclosure may include a third barrier 193. The third barrier 193 may have a structure extending from a hydrogen blocking layer 190.

According to one embodiment of the present disclosure, the third barrier 193 does not overlap with the gate electrode 150, the source connection part 130a, and the drain connection part 130b. The third barrier 193 may be disposed in the third hole BH3 formed in the insulating layer 180 along the thickness direction.

The third barrier 193 may be formed using the same material as the first barrier 191, the second barrier 192, and the hydrogen blocking layer 190 through the same process. The third barrier 193 may be formed integrally with the hydrogen blocking layer 190. The third barrier 193 may include at least one of tungsten (W), titanium (Ti), an alloy of molybdenum and titanium (MoTi), chromium (Cr), vanadium (V), and manganese (Mn). The third barrier 193 may include at least one of tungsten oxide (WOx) and chromium oxide (CrOx).

The third barrier 193 contacts with the first barrier 191 and the second barrier 192. According to one embodiment of the present disclosure, one end of the third barrier 193 may contact one end of the first barrier 191, and the other end of the third barrier 193 may contact one end of the second barrier 192.

Referring to FIG. 3, the third barrier 193 may contact the light blocking layer 111.

Referring to FIGS. 1, 2, and 3, the active layer 130 may be spaced apart from the light blocking layer 111 and may be placed between the gate electrode 150 and the light blocking layer 111. The light blocking layer 111 may overlap the channel portion 130n of the active layer 130 and may contact the third barrier 193.

The third barrier 193 may penetrate at least the insulating layer 180 and the buffer layer 120 and come into contact with the light blocking layer 111.

The light blocking layer 111 may be connected to the hydrogen blocking layer 190 through the third barrier 193. Referring to FIG. 2, the hydrogen blocking layer 190 is connected to the source connection part 130a through the first barrier 191. Therefore, light blocking layer 111 may be connected to the source connection part 130a through the third barrier 193, the hydrogen blocking layer 190, and the first barrier 191. Accordingly, the same voltage as the source connection part 130a may be applied to the light blocking layer 111, the hydrogen blocking layer 190, the first barrier 191, the second barrier 192, and the third barrier 193.

Referring to FIG. 1, the first barrier 191, the second barrier 192, and the third barrier 193 may form an area defined by a U-shaped boundary in a plan view. In detail, the area formed by the first barrier 191, the second barrier 192, and the third barrier 193 is open only in the direction in which the gate electrode 150 extends.

The channel portion 130n may be disposed in a U-shaped space formed by the first barrier 191, the second barrier 192, and the third barrier 193 in a planar manner.

According to one embodiment of the present disclosure, the channel portion 130n of the active layer 130 may be surrounded and protected by a light blocking layer 111, a hydrogen blocking layer 190, a first barrier 191, a second barrier 192, and a third barrier 193. Since the light blocking layer 111, the hydrogen blocking layer 190, the first barrier 191, the second barrier 192, and the third barrier 193 function as hydrogen barriers, the channel portion 130n of the active layer 130 may be protected from hydrogen flowing in from the outside.

FIG. 4 is a cross-sectional view of a thin film transistor 200 according to another embodiment of the present disclosure. Hereinafter, in order to avoid redundant description, components already described are briefly described or descriptions of components already described are omitted.

Referring to FIG. 4, the gate insulating layer 140 may be disposed over the entire upper portion of the substrate 110 without being patterned. For example, the gate insulating layer 140 may cover all of the channel portion 130n, the source connection part 130a, and the drain connection part 130b except for the contact region.

FIG. 5 is a cross-sectional view of a thin film transistor 300 according to another embodiment of the present disclosure.

Referring to FIG. 5, a source electrode 160 and a drain electrode 170 may be disposed on a first insulating layer 181.

The source electrode 160 and the drain electrode 170 may each include at least one of molybdenum (Mo), aluminum (Al), chromium (Cr), gold (Au), titanium (Ti), nickel (Ni), neodymium (Nd), copper (Cu), and alloys thereof. The source electrode 160 and the drain electrode 170 may each be formed of a single layer made of a metal or an alloy of metals, or may be formed of a multilayer of two or more layers.

FIG. 6 is a cross-sectional view of a thin film transistor 400 according to another embodiment of the present disclosure.

Referring to FIG. 6, the active layer 130 may have a multilayer structure.

According to another embodiment of the present disclosure, the active layer 130 may include a first oxide semiconductor layer 131 and a second oxide semiconductor layer 132 on the first oxide semiconductor layer 131.

The first oxide semiconductor layer 131 supports the second oxide semiconductor layer 132. Therefore, the first oxide semiconductor layer 131 is also called a support layer. The main channel portion may be formed in the second oxide semiconductor layer 132. However, one embodiment of the present disclosure is not limited thereto, and the main channel portion may be formed in the first oxide semiconductor layer 131.

Another embodiment of the present disclosure provides a display apparatus including a thin film transistor TFT.

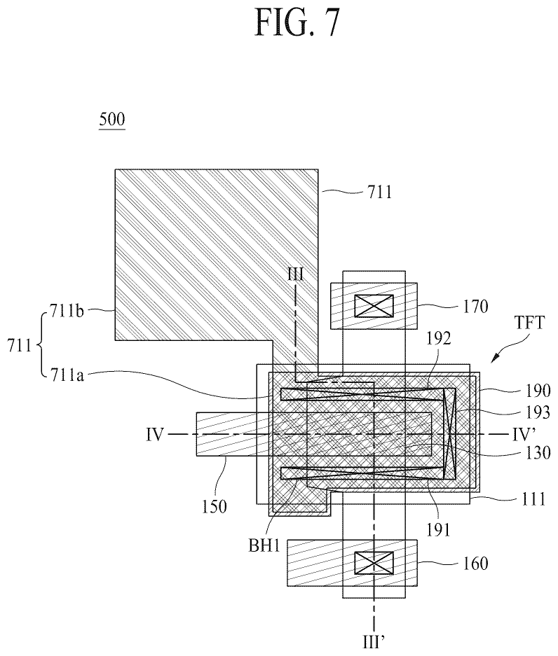

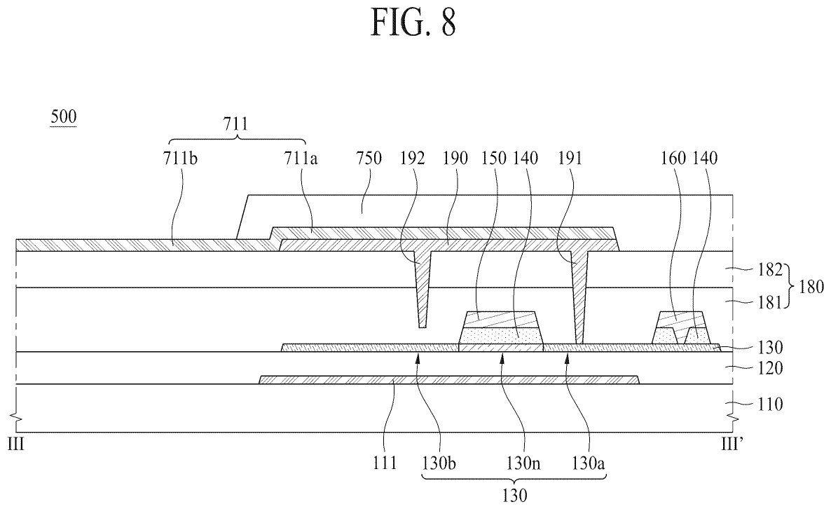

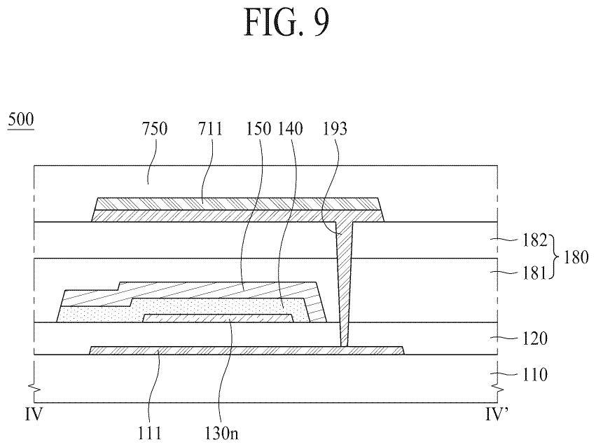

FIG. 7 is a partial plan view of a display apparatus 500 according to another embodiment of the present disclosure, FIG. 8 is a cross-sectional view taken along line III-III′ of FIG. 7 according to one embodiment of the present disclosure, and FIG. 9 is a cross-sectional view taken along line IV-IV′ of FIG. 7 according to one embodiment of the present disclosure.

A display apparatus 500 according to another embodiment of the present disclosure includes a thin film transistor TFT and a first electrode 711 connected to the thin film transistor TFT. The first electrode 711 is, for example, a pixel electrode that drives a pixel.

According to another embodiment of the present disclosure, the thin film transistor TFT of the display apparatus 500 may be applied to the thin film transistor 100, 200, 300, 400 described above.

The thin film transistor TFT of a display apparatus 500 may include an active layer 130, a gate electrode 150 on the active layer 130, an insulating layer 180 on the gate electrode 150, a hydrogen blocking layer 190 on the insulating layer 180, a first barrier 191, a second barrier 192, and a third barrier 193 connected to the hydrogen blocking layer 190.

The active layer 130 includes a channel portion 130n overlapping with the gate electrode 150, a source connection part 130a connected to one side of the channel portion 130n, and a drain connection part 130b connected to the other side of the channel portion 130n.

The first barrier 191 extends from the hydrogen blocking layer 190 and may penetrate the insulating layer 180 to contact either the source connection part 130a or the drain connection part 130b. The second barrier 192 extends from the hydrogen blocking layer 190 and may be spaced apart from the first barrier 191 with the gate electrode 150 interposed therebetween. The third barrier 193 may have a structure extending from the hydrogen blocking layer 190. The third barrier 193 does not overlap the gate electrode 150, the source connection part 130a, and the drain connection part 130b.

The display apparatus 500 according to another embodiment of the present disclosure may include a light blocking layer 111 disposed on a substrate 110.

The light blocking layer 111 may be connected to the hydrogen blocking layer 190 through the third barrier 193. Referring to FIG. 9, the hydrogen blocking layer 190 is connected to the source connection part 130a through the first barrier 191. Therefore, the light blocking layer 111 may be connected to the source connection part 130a through the third barrier 193, the hydrogen blocking layer 190, and the first barrier 191.

Referring to FIGS. 7 and 8, the first electrode 711 may be connected to the hydrogen blocking layer 190. In detail, at least a portion of the first electrode 711 may be disposed on the hydrogen blocking layer 190 and may contact the hydrogen blocking layer 190.

The region of the first electrode 711 that overlaps with the hydrogen blocking layer 190 may be referred to as a first region 711a. The first region 711a of the first electrode 711 may be referred to as a region that is disposed on the hydrogen blocking layer 190 and comes into contact with the hydrogen blocking layer 190.

Additionally, the first electrode 711 may include a region that does not overlap with the hydrogen blocking layer 190. The region of the first electrode 711 that does not overlap with the hydrogen blocking layer 190 may be referred to as a second region 711b.

The second region 711b of the first electrode 711 may have light transparency. Accordingly, light generated from the display apparatus 500 may be emitted to the outside through the second region 711b of the first electrode 711.

Referring to FIG. 8, a bank layer 750 is disposed at the edge of the first electrode 711. The bank layer 750 defines a light emission area of the display element 710. Referring to FIGS. 8 and 9, the bank layer 750 may cover the entire first area 711a of the first electrode 711 that overlaps with the hydrogen blocking layer 190.

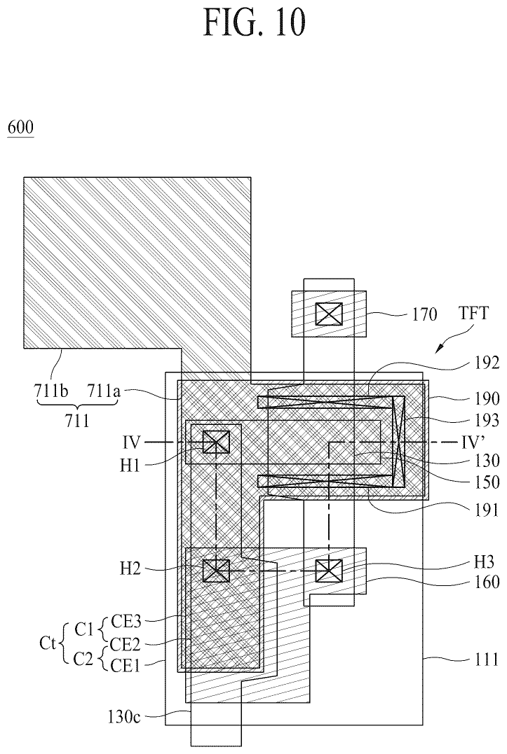

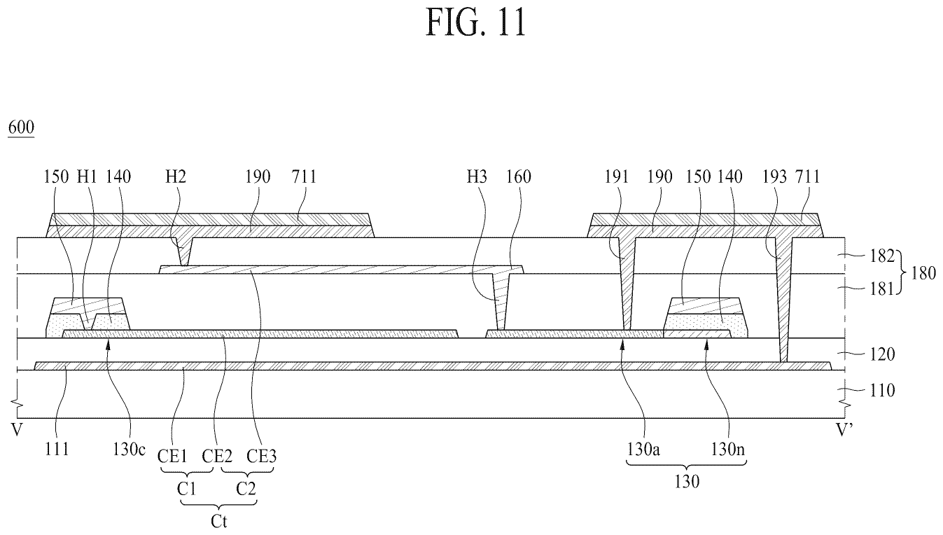

FIG. 10 is a partial plan view of a display apparatus 600 according to another embodiment of the present disclosure, and FIG. 11 is a cross-sectional view taken along line V-V′ of FIG. 10 according to one embodiment of the present disclosure.

A display apparatus 600 according to another embodiment of the present disclosure may include a capacitor Ct. The capacitor Ct may include a first capacitor electrode CE1 and a second capacitor electrode CE2. The capacitor Ct may further include a third capacitor electrode CE3.

According to another embodiment of the present disclosure, the light blocking layer 111 may be a capacitor electrode. The first capacitor electrode CE1 may be connected to the light blocking layer 111. Specifically, the first capacitor electrode CE1 may be formed integrally with the light blocking layer 111. For example, as illustrated in FIG. 11, a portion of the light blocking layer 111 that does not overlap with the channel portion 130n may be the first capacitor electrode CE1.

The light blocking layer 111 may have electrical conductivity and may be connected to the hydrogen blocking layer 190 through the third barrier 193. Referring to FIG. 11, the hydrogen blocking layer 190 is connected to the source connection part 130a through the first barrier 191. Accordingly, the first capacitor electrode CE1 formed integrally with the light blocking layer 111 may be connected to the source connection part 130a of the thin film transistor TFT through the third barrier 193, the hydrogen blocking layer 190, and the first barrier 191.

As a result of this connection, the same voltage as the source connection part 130a may be applied to the first capacitor electrode CE1.

Referring to FIGS. 10 and 11, the second capacitor electrode CE2 may be formed on the same layer as the active layer 130 of the thin film transistor TFT. For example, a conductorized portion 130c formed by patterning and conducting an active layer forming material may become the second capacitor electrode CE2.

The second capacitor electrode CE2 may be spaced apart from the active layer 130. Referring to FIGS. 10 and 11, the second capacitor electrode CE2 may be connected to the gate electrode 150 of the thin film transistor. Specifically, referring to FIG. 11, one end of the second capacitor electrode CE2 may be connected to the gate electrode 150 through the first contact hole H1. As a result, the same voltage as the gate electrode 150 may be applied to the second capacitor electrode CE2.

According to another embodiment of the present disclosure, a first capacitor electrode CE1 and a second capacitor electrode CE2 may overlap each other to form a first capacitor C1.

A capacitor Ct according to another embodiment of the present disclosure may further include a third capacitor electrode CE3. The third capacitor electrode CE3 may be disposed on the first insulating layer 181.

The third capacitor electrode CE3 may be connected to the source connection part 130a of the thin film transistor TFT through the third contact hole H3 formed in the first insulating layer 181. In addition, the third capacitor electrode CE3 may be connected to the hydrogen blocking layer 190 through the second contact hole H2 formed in the second insulating layer 182.

As a result of this connection, the same voltage as the source connection part 130a may be applied to the third capacitor electrode CE3. Additionally, the same voltage as the first capacitor electrode CE1 may be applied to the third capacitor electrode CE3.

The third capacitor electrode CE3 may overlap with the second capacitor electrode CE2. The second capacitor electrode CE2 and the third capacitor electrode CE3 may overlap to form a second capacitor C2. One capacitor Ct may be formed by the first capacitor C1 and the second capacitor C2.

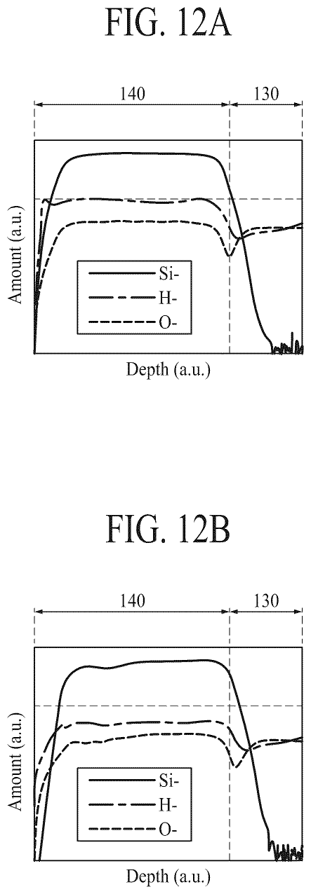

FIGS. 12A and 12B illustrate graphs of the hydrogen content included in a thin film transistor.

In detail, FIG. 12A is a Time-of-Flight Secondary Ion Mass Spectrometry (TOF-SIMS) analysis result for a comparative example (Comp. Ex) thin film transistor having the structure of FIG. 1, but excluding the hydrogen blocking layer 190, the first barrier 191, the second barrier 192, and the third barrier 193.

In addition, FIG. 12B is a TOF-SIMS analysis result for a thin film transistor of Example 1 (Ex. 1) including a hydrogen blocking layer 190, a first barrier 191, a second barrier 192, and a third barrier 193, as illustrated in FIG. 1. Example 1 (Ex. 1) corresponds to one embodiment of the present disclosure.

In the thin film transistors of Comparative Example (Comp. Ex) and Example 1 (Ex. 1), the active layer 130 includes an IGZO (InGaZnO) oxide semiconductor material, and the gate insulating layer 140 includes silicon oxide (SiOx). In the thin film transistor of Example 1 (Ex. 1), the hydrogen blocking layer 190, the first barrier 191, the second barrier 192, and the third barrier 193 include tungsten oxide (WOx).

FIGS. 12A and 1B show TOF-SIMS analysis results measured in the section from the upper surface of the gate insulating layer 140 to the active layer 130.

Comparing the analysis results shown in FIG. 12A and FIG. 12B, the hydrogen (H) content included in the gate insulating layer 140 of the thin film transistor according to is less than the hydrogen (H) content included in the gate insulating layer 140 of the thin film transistor according to the comparative example (Comp. Ex). Therefore, it may be sufficiently predicted and confirmed that the influence of hydrogen (H) on the active layer 130 of the thin film transistor according to Example 1 is less than the influence of hydrogen (H) on the active layer 130 of the thin film transistor according to the comparative example.

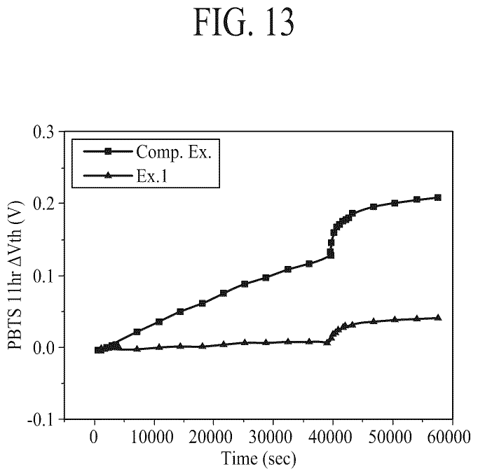

FIG. 13 is a positive-bias temperature stress (PBTS) graph for a thin film transistor according to one embodiment of the present disclosure. Specifically, the thin film transistors applied to the TOF-SIMS analysis of FIG. 12 were applied to the PBTS test.

Referring to FIG. 13, when a high temperature approximately 100° C. stress is applied to a thin film transistor of a comparative example (Comp. Ex) that does not include a hydrogen blocking layer 190, a first barrier 191, a second barrier 192, and a third barrier 193, it may be confirmed that the change ΔVth in the threshold voltage Vth increases. On the other hand, it may be confirmed that even when a high temperature stress is applied to the thin film transistor of Example 1 (Ex. 1), the change ΔVth in the threshold voltage is not large.

According to one embodiment of the present disclosure, since the hydrogen blocking layer 190, the first barrier 191, the second barrier 192, and the third barrier 193 block hydrogen from flowing into the channel portion 130n of the thin film transistor, even if the thin film transistor is exposed to a high temperature, the change in threshold voltage ΔVth is not large. In this way, the thin film transistor according to one embodiment of the present disclosure may have excellent electrical stability.

The thin film transistor 100, 200, 300, 400, TFT according to one embodiment of the present disclosure having excellent resistance to hydrogen (H) may be particularly applied to a driving transistor of a display apparatus.

Hereinafter, a display apparatus including a thin film transistor according to one embodiment of the present disclosure will be described in detail.

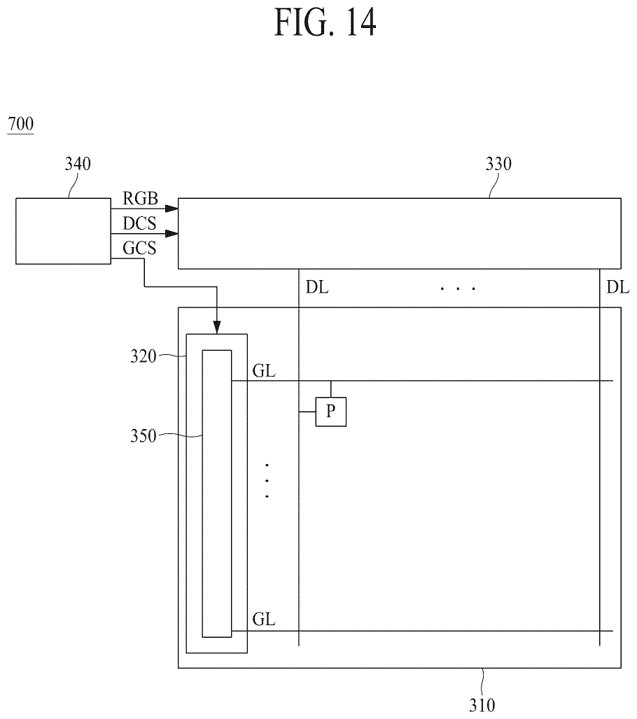

FIG. 14 is a schematic diagram of a display apparatus 700 according to another embodiment of the present disclosure.

A display apparatus 700 according to another embodiment of the present disclosure may include a display panel 310, a gate driver 320, a data driver 330, and a control unit 340 (e.g., a circuit).

The gate lines GL and data lines DL are disposed on the display panel 310, and pixels P are disposed at the intersection of the gate lines GL and the data lines DL. An image is displayed by driving the pixels P.

The control unit 340 controls the gate driver 320 and the data driver 330.

The control unit 340 outputs a gate control signal GCS for controlling the gate driver 320 and a data control signal DCS for controlling the data driver 330 using a signal supplied from an external system. In addition, the control unit 340 samples input image data input from an external system, rearranges it, and supplies the rearranged image data RGB to the data driver 330.

The gate control signal GCS may include a gate start pulse GSP, a gate shift clock GSC, a gate output enable signal GOE, a start signal Vst, a gate clock GCLK, or the like. In addition, the gate control signal GCS may include control signals for controlling a shift register.

The data control signal DCS may include a source start pulse SSP, a source shift clock signal SSC, a source output enable signal SOE, a polarity control signal POL, or the like.

The data driver 330 supplies data voltage to the data lines DL of the display panel 310. Specifically, the data driver 330 may convert image data RGB input from the control unit 340 into analog data voltage and supply the data voltage to the data lines DL.

The gate driver 320 may include a shift register 350. The shift register 350 sequentially supplies gate pulses to the gate lines GL during one frame using a start signal and a gate clock transmitted from the control unit 340.

Using the shift register 350, the gate driver 320 may sequentially supply gate pulses GP to the gate lines GL during one frame. Here, one frame refers to a period during which one image is output through the display panel. In addition, the gate driver 320 supplies a gate off signal Goff capable of turning off the switching element to the gate lines GL during the remaining period during which the gate pulse GP is not supplied during one frame. Hereinafter, the gate pulse GP and the gate off signal Goff are collectively referred to as a scan signal SS.

According to one embodiment of the present disclosure, the gate driver 320 may be mounted on the substrate 110. In this way, a structure in which the gate driver 320 is directly mounted on the substrate 110 is called a Gate In Panel (GIP) structure.

The display panel 310 may include a plurality of pixels P. Each pixel P may be disposed on a substrate 110.

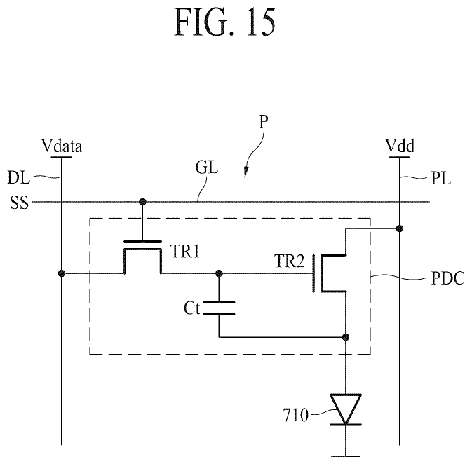

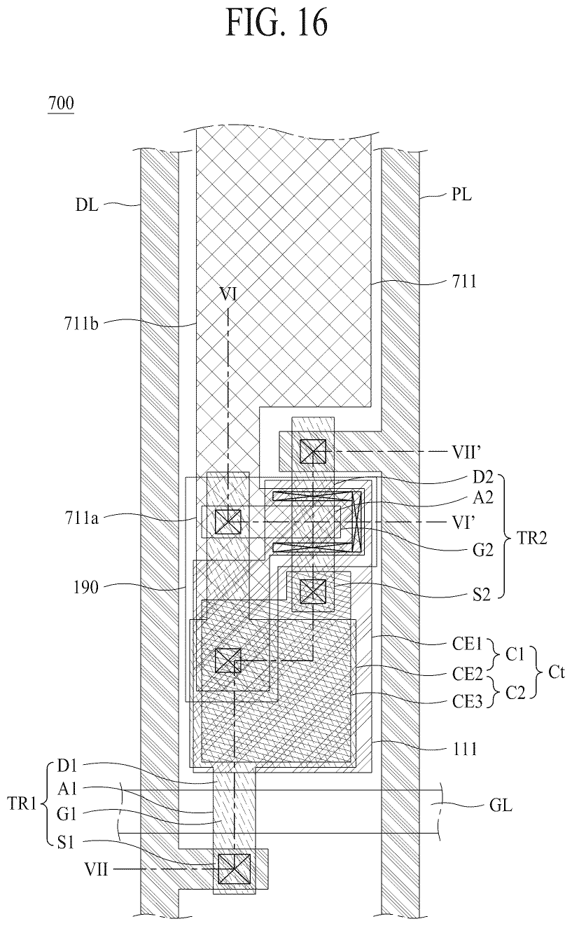

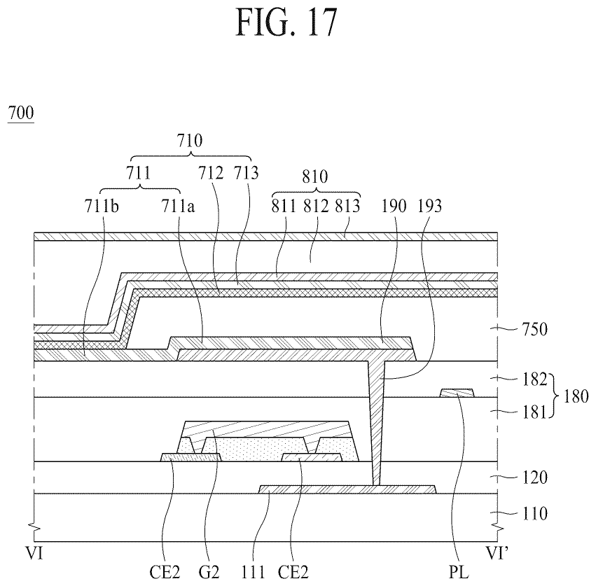

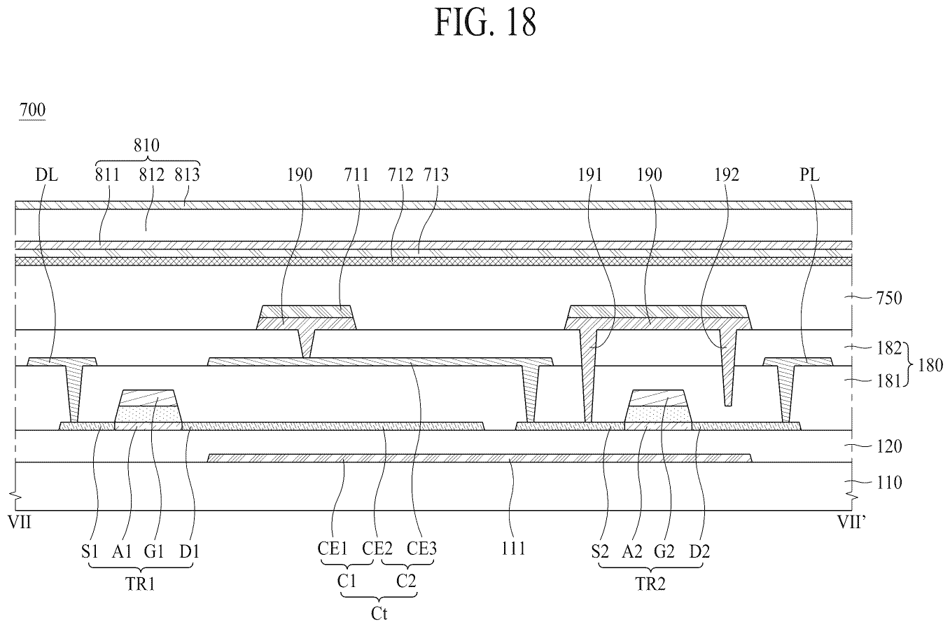

FIG. 15 is a circuit diagram for one pixel P shown in FIG. 14 according to one embodiment of the present disclosure, FIG. 16 is a plan view for the pixel P shown in FIG. 15 according to one embodiment of the present disclosure, FIG. 17 is a cross-sectional view taken along line VI-VI′ of FIG. 16 according to one embodiment of the present disclosure, and FIG. 18 is a cross-sectional view taken along line VII-VII′ of FIG. 16 according to one embodiment of the present disclosure.

The circuit diagram of FIG. 15 is an equivalent circuit diagram for a pixel P of a display apparatus 700 including an organic light emitting diode (OLED) as a display element 710.

The pixel P includes a display element 710 and a pixel driver PDC that drives the display element 710. Therefore, the display apparatus 700 according to another embodiment of the present disclosure may include a display element 710 and a pixel driver PDC that drives the display element 710.

The pixel driver PDC may include the thin film transistor 100, 200, 300, 400, TFT described above. Specifically, the pixel driver PDC of FIG. 15 includes a first thin film transistor TR1 and a second thin film transistor TR2.

The first thin film transistor TR1 is connected to the gate line GL and the data line DL, and is turned on or off by the scan signal SS supplied through the gate line GL.

The data line DL provides a data voltage Vdata to the pixel driver PDC, and the first thin film transistor TR1 controls the application of the data voltage Vdata. The first thin film transistor TR1 switches whether or not the data voltage Vdata is applied, and is called a switching transistor.

The driving power line PL provides a driving voltage Vdd to the display element 710, and the second thin film transistor TR2 controls the driving voltage Vdd. The driving voltage Vdd is a pixel driving voltage for driving the organic light emitting diode (OLED), which is the display element 710.

When the first thin film transistor TR1 is turned on by a scan signal SS applied through the gate line GL from the gate driver 320, the data voltage Vdata supplied through the data line DL is supplied to the gate electrode G2 of the second thin film transistor TR2 connected to the display element 710. The data voltage Vdata is charged in the capacitor Ct formed between the gate electrode G2 and the source electrode S2 of the second thin film transistor TR2. The capacitor Ct of FIG. 15 is a storage capacitor Cst.

The amount of current supplied to the organic light emitting diode OLED, which is a display element 710, through the second thin film transistor TR2 is controlled according to the data voltage Vdata, and accordingly, the gradation of light output from the display element 710 may be controlled. The second thin film transistor TR2 that controls the gradation of light output from the display element 710 is also called a driving transistor.

Since the driving transistor controls the gradation of light, even a slight change in the driving transistor may affect the image displayed on the display apparatus 700. For example, even if the electrical characteristics of the driving transistor slightly change, defects such as vertical lines may occur on the screen displayed on the display apparatus 700. Therefore, it is necessary to block factors that affect the electrical characteristics of the driving transistor as much as possible.

For example, the electrical characteristics of the driving transistor may easily change due to hydrogen (H). Therefore, it is necessary to prevent the driving transistor from being affected by hydrogen.

The channel portion of the thin film transistor 100, 200, 300, 400, TFT according to embodiments of the present disclosure is protected from hydrogen by the hydrogen blocking layer 190, the first barrier 191, the second barrier 192, and the third barrier 193. Therefore, the thin film transistor 100, 200, 300, 400, TFT according to embodiments of the present disclosure may be particularly usefully applied to the second thin film transistor TR2, which is a driving transistor.

Referring to FIG. 16 and FIG. 17, a first thin film transistor TR1 and a second thin film transistor TR2 are disposed on a substrate 110.

The substrate 110 may be made of glass or plastic. As the substrate 110, a plastic having flexible properties, for example, polyimide (PI), may be used.

The light blocking layer 111 is disposed on a substrate 110. The light blocking layer 111 may have light blocking properties. The light blocking layer 111 may block light incident from the outside to protect the active layer A2. A part of the light blocking layer 111 may become a first capacitor electrode CE1. Referring to FIGS. 16 and 17, the light blocking layer 111 and the first capacitor electrode CE1 may be integrally formed.

A buffer layer 120 is disposed on the light blocking layer 111. The buffer layer 120 is made of an insulating material and protects the channel portions from moisture or oxygen flowing in from the outside.

An active layer A1, A2 is disposed on a buffer layer 120. The active layer 130 may include an oxide semiconductor material. The active layer A1, A2 may include an oxide semiconductor layer made of an oxide semiconductor material.

The portion of the active layer A1, A2 may be conductorized to serve as a source connection part and a drain connection part. The source connection part and the drain connection part may also serve as a source electrode S1, S2 and a drain electrode D1, D2.

Additionally, a portion of the active layer may be conductorized to become a capacitor electrode. Specifically, referring to FIG. 18, a portion of the first active layer A1 may be conductorized to become a second capacitor electrode CE2. For example, a drain region of the first thin film transistor TR1 may be extended to become a second capacitor electrode CE2.

A gate insulating layer 140 is disposed on the active layers A1, A2. The gate insulating layer 140 has insulating properties and separates the active layers A1, A2 from the gate electrodes G1, G2. The gate insulating layer 140 may cover the entire upper surface of the active layers A1, A2.

The first gate electrode G1 of a first thin film transistor TR1 and a second gate electrode G2 of a second thin film transistor TR2 are disposed on a gate insulating layer 140.

The second gate electrode G2 of the second thin film transistor TR2 may be connected to the drain region of the first thin film transistor TR1. As a result, the second gate electrode G2 may be connected to the second capacitor electrode CE2 and the first drain electrode D1 of the first thin film transistor TR1.

Referring to FIGS. 16 and 17, a first insulating layer 181 is disposed on the gate electrodes G1, G2, and a third capacitor electrode CE3 is disposed on the first insulating layer 181. The third capacitor electrode CE3 may be disposed to overlap the first capacitor C1 and the second capacitor C2.

Additionally, a data line DL and a driving power line PL may be disposed on the first insulating layer 181. The data line DL may be connected to a first source electrode S1 of a first thin film transistor TR1. The driving power line PL may be connected to a second drain electrode D2 of a second thin film transistor TR2.

The third capacitor electrode CE3 may be connected to the second source electrode S2 of the second thin film transistor TR2.

A second insulating layer 182 may be disposed on the data line DL, the driving power line PL, and the third capacitor electrode CE3. The first insulating layer 181 and the second insulating layer 182 are referred to as an insulating layer 180.

The second insulating layer 182 protects the thin film transistors TR1, TR2. The second insulating layer 182 may also be called a planarizing layer.

A hydrogen blocking layer 190 is disposed on the second insulating layer 182. In addition, a first barrier 191, a second barrier 192, and a third barrier 193 penetrating the insulating layer 180 are disposed within the insulating layer 180.

The first barrier 191, the second barrier 192, and the third barrier 193 may be formed using the same material as the hydrogen blocking layer 190 through the same process. The first barrier 191, the second barrier 192, and the third barrier 193 may be formed integrally with the hydrogen blocking layer 190. The hydrogen blocking layer 190, the first barrier 191, the second barrier 192, and the third barrier 193 may have electrical conductivity.

The first barrier 191 extends from the hydrogen blocking layer 190 and may penetrate the insulating layer 180. The first barrier 191 may penetrate the insulating layer 180 and be connected to the second source electrode S2 of the second thin film transistor TR2.

The second barrier 192 may be spaced apart from the first barrier 191 and connected to the hydrogen blocking layer 190. The second barrier 192 may extend from the hydrogen blocking layer 190 and may be disposed spaced apart from the first barrier 191 with the second gate electrode G2 interposed therebetween. The second barrier 192 may be spaced apart from the second source electrode S2 and the second drain electrode D2.

The third barrier 193 may have a structure extending from the hydrogen blocking layer 190. The third barrier 193 may penetrate the insulating layer 180 and the buffer layer 120 and come into contact with the light blocking layer 111. Accordingly, the same voltage as the second source electrode S2 may be applied to the light blocking layer 111, the hydrogen blocking layer 190, the first barrier 191, the second barrier 192, and the third barrier 193. In addition, the same voltage as the second source electrode S2 may also be applied to the first capacitor electrode CE1 formed integrally with the light blocking layer 111.

The first capacitor C1 may be formed by overlapping a first capacitor electrode CE1 and a second capacitor electrode CE2. A second capacitor C2 may be formed by overlapping a second capacitor electrode CE2 and a third capacitor electrode CE3. One capacitor Ct is formed by the first capacitor C1 and the second capacitor C12.

A first electrode 711 of a display element 710 is disposed on an insulating layer 180. Referring to FIG. 18, the first electrode 711 of a display element 710 may be disposed on a second insulating layer 182. The first electrode 711 is, for example, a pixel electrode.

The first electrode 711 may be connected to the hydrogen blocking layer 190. In detail, at least a portion of the first electrode 711 may be disposed on the hydrogen blocking layer 190 and may contact the hydrogen blocking layer 190.

The region of the first electrode 711 that overlaps with the hydrogen blocking layer 190 may be referred to as a first region 711a. The first region 711a of the first electrode 711 may be referred to as a region that is disposed on the hydrogen blocking layer 190 and comes into contact with the hydrogen blocking layer 190.

Additionally, the first electrode 711 may include a region that does not overlap with the hydrogen blocking layer 190. The region of the first electrode 711 that does not overlap with the hydrogen blocking layer 190 may be referred to as a second region 711b.

The second region 711b of the first electrode 711 may have light transparency. Accordingly, light generated from the display element 710 may be emitted to the outside through the second region 711b of the first electrode 711.

The first electrode 711 may be connected to the third capacitor electrode CE3 through a contact hole formed in the hydrogen blocking layer 190 and the second insulating layer 182. In addition, the first electrode 711 may be connected to the second source electrode S2 of the second thin film transistor TR2 through the hydrogen blocking layer 190 and the first barrier 191.

The bank layer 750 is disposed at the edge of the first electrode 711. The bank layer 750 defines a light emission area of the display element 710.

An organic light emitting layer 712 is disposed on a first electrode 711, and a second electrode 713 is disposed on the organic light emitting layer 712. Accordingly, a display element 710 is completed. The display element 710 illustrated in FIG. 17 is an organic light emitting diode (OLED). Therefore, a display apparatus 1000 according to an embodiment of the present disclosure is an organic light emitting display apparatus.

According to another embodiment of the present disclosure, light generated from the display element 710 may pass through the second region 711b of the first electrode 711 and be emitted toward the substrate 110. Such a display apparatus 700 may be referred to as a bottom emission display apparatus.

In addition, an encapsulation layer 810 may be disposed on the display element 710. The encapsulation layer 810 may include a first inorganic layer 811, an organic layer 812, and a second inorganic layer 813. The organic layer 812 of the encapsulation layer 810 may include hydrogen. When hydrogen flows into the channel portion of the thin film transistor TR1, TR2, the electrical characteristics of the thin film transistor TR1, TR2 may become unstable.

According to another embodiment of the present disclosure, at least the second thin film transistor TR2 is protected from hydrogen by the hydrogen blocking layer 190, the first barrier 191, the second barrier 192, and the third barrier 193. Accordingly, even if the organic layer 812 of the encapsulation layer 810 includes a large amount of hydrogen, the operating stability of the second thin film transistor TR2 may be secured. As a result, the display apparatus 700 may have excellent and stable display quality.

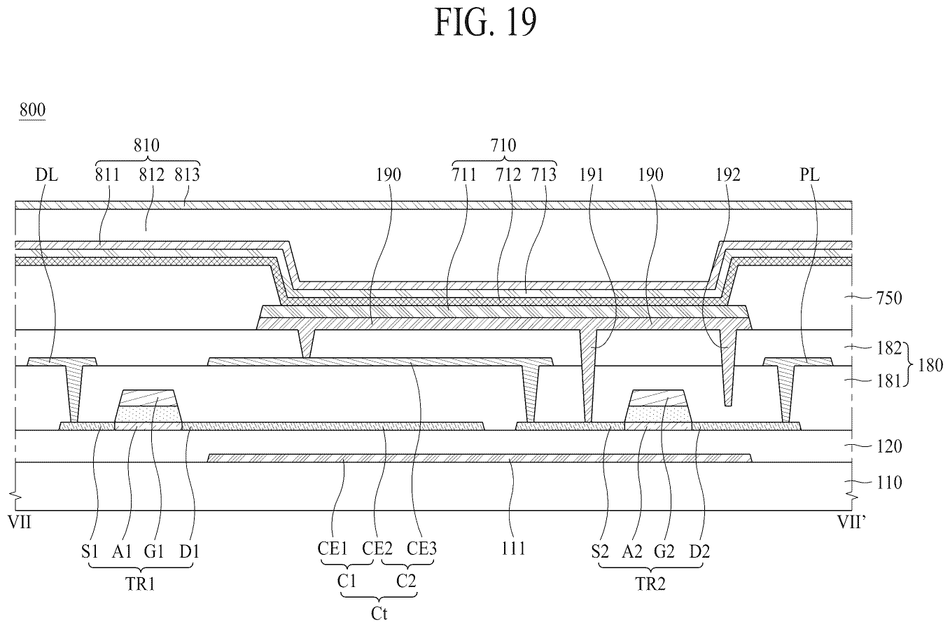

FIG. 19 is a cross-sectional view of a display apparatus 800 according to another embodiment of the present disclosure.

According to another embodiment of the present disclosure, the entire first electrode 711 may be disposed on the hydrogen blocking layer 190. When the hydrogen blocking layer 190 does not have light transparency, light generated from the display element 710 may be emitted toward the hydrogen blocking layer 190.

According to another embodiment of the present disclosure, the first electrode 711 may have a light reflecting property. When the first electrode 711 has a light reflecting property, light generated from the display element 710 may be emitted in the opposite direction of the substrate 110. Such a display apparatus 700 may be called a top emission display apparatus.

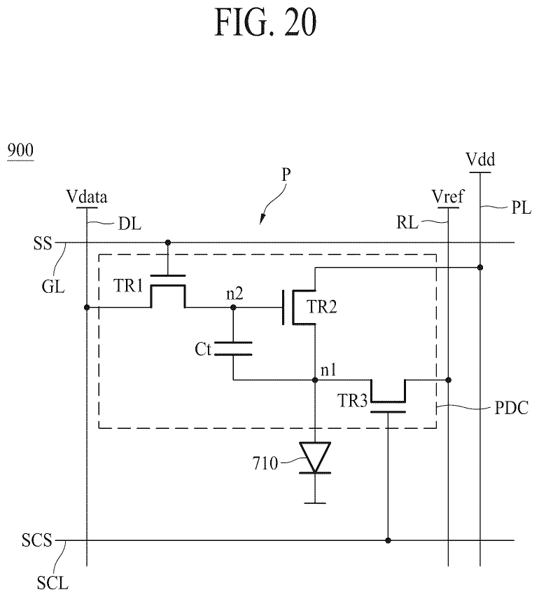

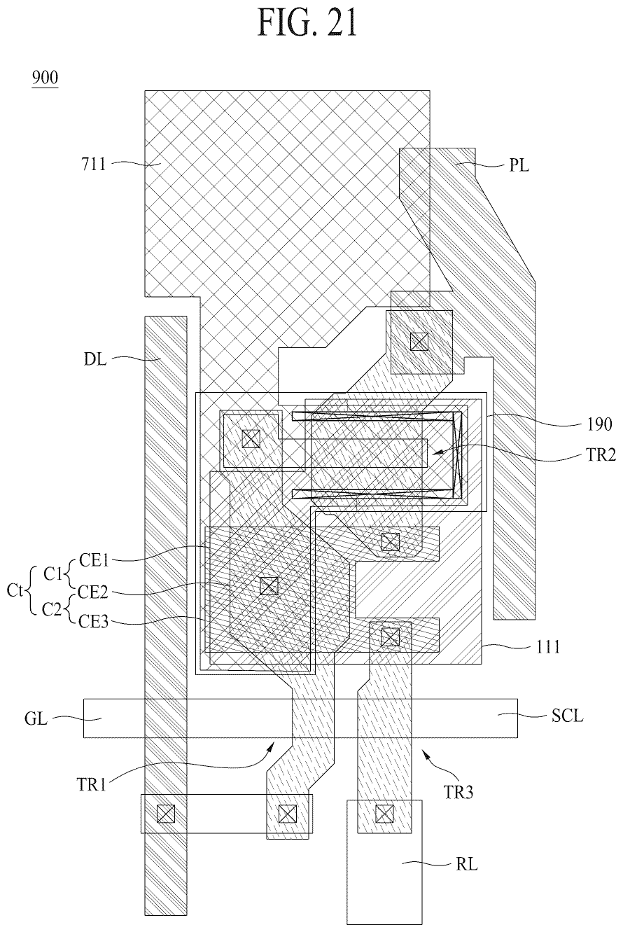

FIG. 20 is a circuit diagram for one pixel P of a display apparatus 900 according to another embodiment of the present disclosure, and FIG. 21 is a plan view for the pixel P of FIG. 20 according to one embodiment of the present disclosure.

FIG. 20 is an equivalent circuit diagram for a pixel P of an organic light emitting display apparatus.

The pixel P of the display apparatus 900 illustrated in FIG. 20 includes an organic light emitting diode OLED as a display element 710 and a pixel driver PDC that drives the display element 710. The display element 710 is connected to the pixel driver PDC.

In the pixel P, signal lines DL, GL, PL, RL, SCL that supply signals to the pixel driver PDC are disposed.

A data voltage Vdata is supplied to a data line DL, a scan signal SS is supplied to a gate line GL, a driving voltage Vdd for driving pixels is supplied to a driving power line PL, a reference voltage Vref is supplied to a reference line RL, and a sensing control signal SCS is supplied to a sensing control line SCL.

According to another embodiment of the present disclosure, the gate line GL of the n-th pixel P and the gate line of the n−1th pixel P adjacent to it may serve as the sensing control line SCL of the n-th pixel P. Alternatively, the gate line GL of the n-th pixel P may serve as the sensing control line SCL of the n-th pixel P.

The pixel driver PDC includes, for example, a first thin film transistor TR1 serving as a switching transistor connected to a gate line GL and a data line DL, a second thin film transistor TR2 acting as a driving transistor, that controls the amount of current output to a display element 710 according to a data voltage Vdata transmitted through the first thin film transistor TR1, and a third thin film transistor TR3, functioning as a reference transistor, for detecting a characteristic of the second thin film transistor TR2.

The capacitor Ct is disposed between the gate electrode of the second thin film transistor TR2 and the display element 710. The capacitor Ct is also called a storage capacitor Cst.

The first thin film transistor TR1 is turned on by a scan signal SS supplied to the gate line GL and transmits the data voltage Vdata supplied to the data line DL to the gate electrode of the second thin film transistor TR2.

The third thin film transistor TR3 is connected to the first node n1 and the reference line RL between the second thin film transistor TR2 and the display element 710, is turned on or off by a sensing control signal SCS, and detects the characteristics of the second thin film transistor TR2, which is a driving transistor, during a sensing period.

The second node n2 connected to the gate electrode G2 of the second thin film transistor TR2 is connected to the first thin film transistor TR1. A capacitor Ct is formed between the second node n2 and the first node n1.

When the first thin film transistor TR1 is turned on, the data voltage Vdata supplied through the data line DL is supplied to the gate electrode of the second thin film transistor TR2. The data voltage Vdata is charged in the capacitor Ct formed between the gate electrode G2 and the source electrode S2 of the second thin film transistor TR2.

When the second thin film transistor TR2 is turned on, current is supplied to the display element 710 through the second thin film transistor TR2 by the driving voltage Vdd that drives the pixel, and light is output from the display element 710.

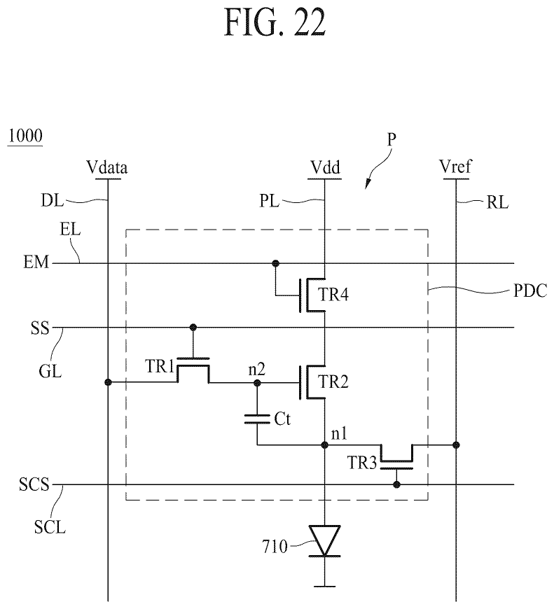

FIG. 22 is a circuit diagram for one pixel P of a display apparatus 1000 according to another embodiment of the present disclosure.

The pixel P included in the display apparatus 1000 of FIG. 22 includes an organic light emitting diode (OLED) as a display element 710 and a pixel driver PDC that drives the display element 710. The display element 710 is connected to the pixel driver PDC.

In the pixel P, signal lines DL, EL, GL, PL, RL, SCL that supply signals to the pixel driver PDC are disposed.

A data voltage Vdata is supplied to a data line DL, a scan signal SS is supplied to a gate line GL, a driving voltage Vdd for driving pixels is supplied to a driving power line PL, an initialization signal Vini is supplied to a reference line RL, and a sensing control signal SCS is supplied to a sensing control line SCL.

The pixel driver PDC includes, for example, a first thin film transistor TR1 as a switching transistor, connected to a gate line GL and a data line DL, a second thin film transistor TR2, acting as a driving transistor, that controls the amount of current output to a display element 710 according to a data voltage Vdata transmitted through the first thin film transistor TR1, and a third thin film transistor TR3, functioning as a sensing transistor, for detecting a characteristic of the second thin film transistor TR2.

The capacitor Ct is disposed between the gate electrode of the second thin film transistor TR2 and the display element 710. The capacitor Ct disposed between the first node n1 and the second node n2 is also called a storage capacitor Cst.

The first thin film transistor TR1 is turned on by a scan signal SS supplied to the gate line GL and transmits the data voltage Vdata supplied to the data line DL to the gate electrode of the second thin film transistor TR2.

The third thin film transistor TR3 is connected to the first node n1 and the reference line RL between the second thin film transistor TR2 and the display element 710, is turned on or off by a sensing control signal SCS, and detects the characteristics of the second thin film transistor TR2, which is a driving transistor, during a sensing period.

The second node n2 connected to the gate electrode G2 of the second thin film transistor TR2 is connected to the first thin film transistor TR1.

When the first thin film transistor TR1 is turned on, the data voltage Vdata supplied through the data line DL is supplied to the gate electrode of the second thin film transistor TR2. The data voltage Vdata is charged in the capacitor Ct formed between the gate electrode G2 and the source electrode S2 of the second thin film transistor TR2.

An emission control signal EM is supplied to the emission control line EL.

The fourth thin film transistor TR4 is a light emitting control transistor for controlling the light emitting timing of the second thin film transistor TR2. The fourth thin film transistor TR4 transmits the driving voltage Vdd to the second thin film transistor TR2 or blocks the driving voltage Vdd according to the emission control signal EM. When the fourth thin film transistor TR4 is turned on, current is supplied to the second thin film transistor TR2, and light is output from the display element 710.

A pixel driver PDC according to another embodiment of the present disclosure may be formed in various structures other than the structures described above. For example, the pixel driver PDC may include three thin film transistors or may include five or more thin film transistors. In addition, the pixel driver PDC may include two or more capacitors.

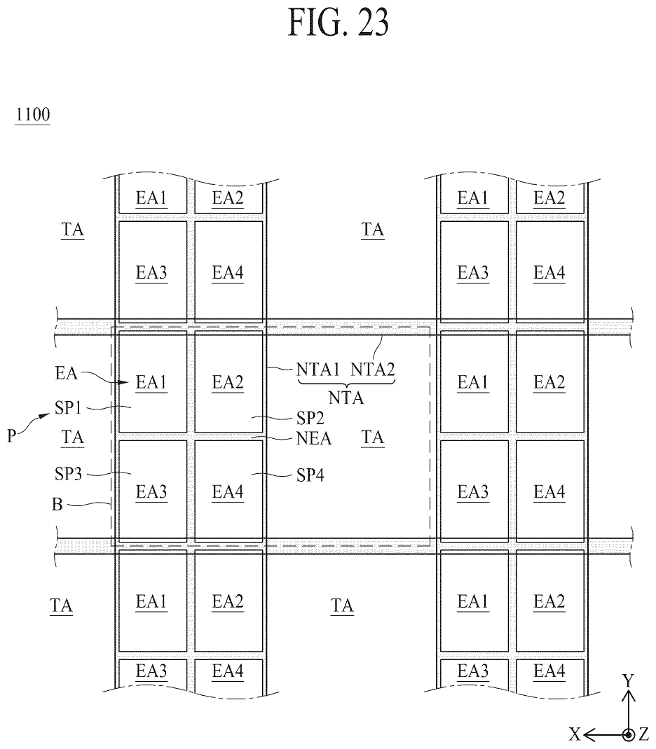

FIG. 23 is a schematic diagram of a part of a display panel of a display apparatus 1100 according to another embodiment of the present disclosure.

The display panel of the display apparatus 1100 of FIG. 23 includes a transparent region that may transmit external light and a non-transparent region that does not transmit external light. Due to the transparent region, the display region or the display panel may have high light transmittance. Such a display apparatus 1100 is also called a “transparent display apparatus.”

Referring to FIG. 23, a display apparatus 1100 according to another embodiment of the present disclosure includes a transmissive area TA and a non-transmissive area NTA.

The transparent area TA is an area that allows most of the light incident from the outside to pass through, and the non-transparent area NTA is an area that does not allow most of the light incident from the outside to pass through. For example, the light transmittance of the transparent area TA may be 90% or more, and the light transmittance of the non-transparent area NTA may be less than 50%. Due to the transparent areas TA, an object or background disposed on the back surface of the display apparatus 1100 may be recognized by the user.

The non-transparent area NTA may include a first non-transparent area NTA1, a second non-transparent area NTA2, and a pixel P.

The pixel P may be disposed in an intersection area where the first non-transparent area NTA1 and the second non-transparent area NTA2 intersect. The pixel P emits light to display an image.

The pixel P includes a light emission area EA. The light emission area EA is an area that emits light.

The pixel P may include a first subpixel SP1, a second subpixel SP2, a third subpixel SP3, and a fourth subpixel SP4. The first subpixel SP1 may include a first light emission area EA1 that emits a first color light, and the second subpixel SP2 may include a second light emission area EA2 that emits a second color light. The third subpixel SP3 may include a third light emission area EA3 that emits a third color light, and the fourth subpixel SP4 may include a fourth light emission area EA4 that emits a fourth color light.

For example, the first to fourth light emission areas EA1, EA2, EA3, EA4 may all emit light of different colors. Specifically, the first light emission area EA1 may emit green light, the second light emission area EA2 may emit red light, the third light emission area EA3 may emit blue light, and the fourth light emission area EA4 may emit white light. However, another embodiment of the present disclosure is not limited thereto.

Additionally, the arrangement order of each subpixel SP1, SP2, SP3, SP4 may be changed in various ways.

The first non-transparent area NTA1 may be disposed to extend in a first direction Y-axis direction and overlap at least partly with the light emission areas EA1, EA2, EA3, EA4. A plurality of first non-transparent areas NTAs may be provided in the display panel, and a transparent area TA may be provided between two adjacent first non-transparent areas NTAs. In the first non-transparent area NTA1, signal lines extending in the first direction (Y-axis direction) and touch lines extending in the first direction Y-axis direction may be disposed to be spaced apart from each other.

The signal lines may include, for example, at least one of a pixel power line VDD, a common power line VSS, a reference line REF, and a data line.

The second non-transparent area NTA2 may be disposed to extend in the second direction (X-axis direction) and overlap at least partly with the light emission areas EA1, EA2, EA3, EA4. A plurality of second non-transparent areas NTA may be provided on the display panel, and a transparent area TA may be provided between two adjacent second non-transparent areas NTA2. A signal line and a touch bridge line may be disposed to be spaced apart from each other in the second non-transparent areas NTA2.

According to another embodiment of the present disclosure, the hydrogen blocking layer 190 may be disposed in the pixel P. In addition, the first barrier 191, the second barrier 192, and the third barrier 193 may also be disposed in the pixel P.

According to another embodiment of the present disclosure, the hydrogen blocking layer 190, the first barrier 191, the second barrier 192, and the third barrier 193 may not be disposed in the transmission area TA.

The first electrode 711 may be disposed in the pixel P. According to another embodiment of the present disclosure, the first electrode 711 may have light transparency. Accordingly, the first electrode 711 may also be disposed in the transparent area TA. For example, the first electrode 711 disposed in the pixel P may be disposed to extend to the transparent area TA.

The present disclosure described above is not limited to the above-described embodiments and the attached drawings, and it will be apparent to those skilled in the art that various substitutions, modifications, and changes are possible within a scope that does not depart from the technical subject matter of the present disclosure. The scope of the present disclosure is indicated in the claims below, and all changes or modified forms derived from the meaning, scope, and equivalent concepts of the claims should be interpreted as being included in the scope of the present disclosure.

In a thin film transistor according to one embodiment of the present disclosure, the hydrogen blocking layer and the barrier may efficiently block hydrogen flowing into the channel portion of the active layer. As a result, the channel portion is efficiently protected from hydrogen, and the electrical stability of the thin film transistor may be improved.

The hydrogen blocking layer and the barrier may include at least one of tungsten W, titanium Ti, an alloy of molybdenum and titanium MoTi, chromium Cr, vanadium V, and manganese Mn. In particular, the hydrogen blocking layer and the barrier may include tungsten oxide WOx, and the tungsten oxide WOx has a porous structure and may effectively block hydrogen and act as a barrier for hydrogen blocking.

According to one embodiment of the present disclosure, the first electrode of the light emitting element may be disposed on the hydrogen blocking layer. In addition, the barrier connected to the hydrogen blocking layer may be connected to the source connection part or the drain connection part of the active layer, and may serve as a wiring. Therefore, according to one embodiment of the present disclosure, the first electrode of the light emitting element may be electrically connected to the thin film transistor by the hydrogen blocking layer and the barrier.

The display apparatus according to another embodiment of the present disclosure including the above thin film transistor may have excellent hydrogen blocking property and may have excellent electrical stability and reliability. Accordingly, a display apparatus according to another embodiment of the present disclosure may have excellent display performance.

In addition to the effects mentioned above, other features and advantages of the present disclosure are described below, and those skilled in the art to which the present disclosure belongs may clearly understand from such description and explanation.

What is claimed is:

1. A thin film transistor comprising:
an active layer;
a gate electrode on the active layer;
an insulating layer on the gate electrode;
a hydrogen blocking layer on the insulating layer;
a first barrier connected to the hydrogen blocking layer; and
a second barrier spaced apart from the first barrier, the second barrier connected to the hydrogen blocking layer,
wherein the active layer comprising:
a channel portion overlapping the gate electrode;
a source connection part connected to one side of the channel portion; and
a drain connection part connected to another side of the channel portion,
wherein the first barrier extends from the hydrogen blocking layer and contacts one of the source connection part and the drain connection part by penetrating the insulating layer, and
wherein the second barrier extends from the hydrogen blocking layer and is spaced apart from the first barrier with the gate electrode being therebetween.

2. The thin film transistor of claim 1, wherein the second barrier overlaps the other one of the source connection part and the drain connection part in a plan view of the thin film transistor, and is spaced apart from the other one of the source connection part and the drain connection part.

3. The thin film transistor of claim 1, wherein the first barrier is in a first hole in the insulating layer along a thickness direction and the second barrier is in a second hole in the insulating layer along the thickness direction.

4. The thin film transistor of claim 3, wherein each of the first hole and the second hole has a slit shape.

5. The thin film transistor of claim 1, further comprising:
a third barrier extending from the hydrogen blocking layer, the third barrier non-overlapping with the gate electrode, the source connection part, or the drain connection part.

6. The thin film transistor of claim 5, wherein the third barrier contacts the first barrier and the second barrier.

7. The thin film transistor of claim 6, wherein the first barrier, the second barrier, and third barrier form an area defined by a U-shaped boundary in a plan view of the thin film transistor, and the channel portion is disposed in the area defined by the U-shaped boundary in the plan view.

8. The thin film transistor of claim 5, further comprising:
a light blocking layer spaced apart from the active layer,
wherein the active layer is between the gate electrode and the light blocking layer,
wherein the light blocking layer overlaps the channel portion of the active layer, and
wherein the third barrier contacts with the light blocking layer.

9. The thin film transistor of claim 8, further comprising:
a buffer layer between the light blocking layer and the active layer,
wherein the third barrier penetrates at least the insulating layer and the buffer layer and contacts the light blocking layer.

10. The thin film transistor of claim 5, wherein the hydrogen blocking layer, the first barrier, the second barrier, and the third barrier include a same material.

11. The thin film transistor of claim 1, wherein the hydrogen blocking layer, the first barrier, and the second barrier include at least one selected from tungsten W, titanium Ti, a molybdenum-titanium alloy MoTi, chromium Cr, vanadium V, and manganese Mn.

12. The thin film transistor of claim 1, wherein the hydrogen blocking layer, the first barrier, and the second barrier include at least one selected from tungsten oxide WOx and chromium oxide CrOx.

13. A display apparatus comprising:
a display element; and
a pixel driver driving the display element, the pixel driver including a thin film transistor,
wherein the thin film transistor comprises:
an active layer;
a gate electrode on the active layer;
an insulating layer on the gate electrode;
a hydrogen blocking layer on the insulating layer;
a first barrier connected to the hydrogen blocking layer; and
a second barrier spaced apart from the first barrier, the second barrier connected to the hydrogen blocking layer,
wherein the active layer comprises:
a channel portion overlapping the gate electrode;
a source connection part connected to one side of the channel portion; and
a drain connection part connected to another side of the channel portion,
wherein the first barrier extends from the hydrogen blocking layer and contacts one of the source connection part and the drain connection part by penetrating the insulating layer, and
wherein the second barrier extends from the hydrogen blocking layer and is spaced apart from the first barrier with the gate electrode being therebetween.

14. The display apparatus of claim 13, further comprising:
a third barrier extending from the hydrogen blocking layer, the third barrier non-overlapping the gate electrode, the source connection part, or the drain connection part.

15. The display apparatus of claim 14, wherein the third barrier contacts the first barrier and the second barrier.

16. The display apparatus of claim 14, further comprising:
a light blocking layer spaced apart from the active layer,
wherein the active layer is between the gate electrode and the light blocking layer,
wherein the light blocking layer overlaps the channel portion of the active layer, and
wherein the third barrier contacts with the light blocking layer.

17. The display apparatus of claim 13, wherein the display element includes a first electrode and the first electrode is connected to the hydrogen blocking layer.

18. The display apparatus of claim 17, wherein at least a portion of the first electrode is on the hydrogen blocking layer and contacts the hydrogen blocking layer.

19. The display apparatus of claim 18, wherein the first electrode comprises:
a first region overlapping the hydrogen blocking layer; and
a second region that is non-overlapping with the hydrogen blocking layer, and
wherein the second region is light transmissive.

20. The display apparatus of claim 18, wherein the first electrode is on the hydrogen blocking layer entirely and the first electrode has a light reflecting property.
